(19) United States
(12) Patent Application Publication
(10) Pub. No.: US 2010/0005364 A1
(43) Pub. Date: Jan. 7, 2010

(54) ENCODING METHOD, ENCODING APPARATUS, DECODING METHOD, AND DECODING APPARATUS USING BLOCK CODE

(76) Inventors: Seiji Higurashi, Tokyo-to (JP); Masayoshi Nishitani, Kanagawa-ken (JP); Toshio Kuroiwa, Kanagawa-ken (JP)

Correspondence Address: CARR & FERRELL LLP, 2200 GENG ROAD, PALO ALTO, CA, 94303, US

(21) Appl. No.: 12/496,468

(22) Filed: Jul. 1, 2009

(30) Foreign Application Priority Data
Jul. 3, 2008 (JP) JP2008-175102

(51) Int. Cl. H03M 13/00; G06F 11/10

(52) U.S. Cl. 714/755; 714/E11.032

(57) ABSTRACT

An input unit receives an information sequence. A first encoding unit performs at least a portion of a block encoding process on the information sequence to generate a first code sequence. A second encoding unit performs the block encoding process on a first check symbol sequence in the generated first code sequence to generate a second code sequence. A generating unit combines a second check symbol sequence in the generated second code sequence with the input information sequence to generate a third code sequence.

### CROSS-REFERENCE TO RELATED APPLICATIONS

The present application claims the priority benefit of Japanese patent application number 2008-175102 filed Jul. 3, 2008, the disclosure of which is incorporated herein by reference.

### BACKGROUND OF THE INVENTION

1 . Field of the Invention

The present invention generally relates to encoding and decoding techniques. More specifically, the present invention relates to a method and apparatus for encoding and decoding using a block code.

2. Description of the Related Art

Product code obtained by two-dimensionally arranging block codes is used as in an error correction technique for correcting data errors. Block encoding is performed in the horizontal direction on each row of information codes in the two-dimensionally arranged product code to generate check symbols in the horizontal direction. Block encoding is also performed in the vertical direction on each column of the information codes and check symbols arranged in the horizontal direction to generate check symbols in the vertical direction. Since the check symbols in the horizontal direction and the vertical direction are generated in the product code, it is possible to improve error correction performance. Reed-Solomon code (“RS” code) or Bose-Chaudhuri-Hocquenghem code (“BCH” code) is used as an example of the block code in, for example, Japanese patent publication number 2004-282600.

When a product code of the RS codes is used to for error correction as described above, a parity P is generated as the check symbol in the horizontal direction and a parity Q is generated as the check symbol in the vertical direction. A parity R, which is a check symbol in the horizontal direction for the parity Q and a check symbol in the vertical direction for the parity P, is also generated. In general, an 8-bit field is used as the Galois field of code. In addition, since the length of a correction code is defined by the Galois field, a maximum code length is 255×8 bits. In this case, the size of data that can be simultaneously processed is 255×255×8 bits. It is difficult to simultaneously process data having a size that is larger than this value. As the size of the Galois field is increased, however, the size of data that can be simultaneously processed is also increased. But in this case, the amount of computation or a circuit size required for code correction is exponentially increased. Therefore, when data has a large size, the data is divided into a plurality of code sequences.

As a pointer erasure method, it is known to use a CRCC error check function instead of the parities P and R. The method uses a CRC code in the horizontal direction instead of the RS code to generate a CRCC. In this pointer erasure method, even when an error of several bits occurs in one row in the horizontal direction, all the bits included in the row are considered as errors and the errors are corrected. This results in a reduction in the efficiency of error correction. For example, when data having a size of 64 kbytes (64×1024 bytes) is treated and a size is 255×257, it is difficult to form a product code with an 8-bit Galois field. In addition, when a plurality of code sequences is used and errors are non-uniformly distributed in the plurality of code sequences, correction performance deteriorates.

It is necessary to improve the efficiency of RS encoding performed on data having a large size of 64 kbytes or more for more efficient transmission. In addition, an RS encoding method which is more efficient and has a higher correction performance than a pointer erasure method is needed.

### SUMMARY OF THE INVENTION

In a first embodiment, an encoding apparatus includes an input unit operative for input of an information sequence; a first encoding unit operative to generate a first code sequence by performing at least a portion of a block encoding process on the input information sequence input; a second encoding unit operative to generate a second code sequence by performing the block encoding process on a first check symbol sequence in the first code sequence; and a generating unit operative to generate a third code sequence by combining a second check symbol sequence in the second code sequence generated with the information sequence.

According to the above-mentioned embodiment, since the third code sequence is generated without the first check symbol sequence, it is possible to improve transmission efficiency during a block encoding process.

According to another embodiment, an encoding apparatus includes an input unit for the input of an information sequence; a dividing unit for dividing the information sequence input by the input unit into a plurality of groups; a first encoding unit to generate a first code sequence for each group by performing at least a portion of a block encoding process on a portion of the information sequence corresponding to each of the plurality of groups divided by the dividing unit; a second encoding unit to generate a second code sequence for each group by performing the block encoding process on a first check symbol sequence in the first code sequence generated by the first encoding unit; a generating unit operative to generate a third code sequence for each group by combining a second check symbol sequence in the second code sequence generated by the second encoding unit with the portion of the information sequence in each of the plurality of groups divided by the dividing unit so as to be associated with each other; a combining unit to combine the third code sequences generated by the generating unit in the plurality of groups; and a third encoding unit to generate a fourth code sequence by performing the block encoding process on the third code sequence combined by the combining unit.

According to the above-mentioned embodiment, an information sequence is divided into a plurality of groups, and the third code sequence without the first check symbol sequence is generated for each group. It is therefore possible to improve transmission efficiency during a block encoding process.

When the information sequence is arranged in a two-dimensional array including a row having a length that is larger than a maximum code length in the block encoding process and a column having a length that is smaller than the maximum code length, the dividing unit may divide the information sequence such that a portion of the information sequence corresponding to one row forms one group. The generating unit may extend the length of each row of the two-dimensional array to perform combination such that the third code sequence is included in one row. The third encoding unit may perform the block encoding process on each column of the third code sequence combined by the combining unit. The dividing unit divides the information sequence such that a portion of the information sequence corresponds to one row of the two-dimensional array that includes a row having a length that is larger than the maximum code length and a column having a length that is smaller than the maximum code length forms one group. It is therefore possible to perform a block encoding process on an information sequence having a size that is larger than the maximum code length.

The second encoding unit makes combinations of the first check symbol sequences in the plurality of groups when the block encoding process is performed different from one another and according to the orders of the first check symbol sequences. Combinations of the first check symbol sequences when the second code sequence is generated are different from each other. It is therefore possible to improve an error detection performance.

According to another embodiment, a decoding apparatus includes: an input unit operative to receive the combined sequence of the second check symbol sequence in the second code sequence and the information sequence from the encoding apparatus and input the received sequence when an encoding apparatus performs at least a portion of a block encoding process on an information sequence to generate a first code sequence, performs the block encoding sequence on a first check symbol sequence in the first code sequence to generate a second code sequence, and combines a second check symbol sequence in the second code sequence with the information sequence; an estimating unit to estimate the first code sequence by performing the same block encoding process as that performed by the encoding apparatus to generate the first code sequence on a portion corresponding to the information sequence in the received sequence input at the input unit; a first processing unit to detect an error in the first check symbol sequence, on the basis of the first check symbol sequence in the first code sequence estimated by the estimating unit and a portion corresponding to the second check symbol sequence in the received sequence input by the input unit; and a second processing unit operative to detect an error in the portion corresponding to the information sequence, on the basis of the first check symbol sequence whose error is detected by the first processing unit and the portion corresponding to the information sequence in the received sequence input by the input unit.

Even when a received sequence without the first check symbol sequence is input, the first check symbol sequence is estimated from the received sequence and error detection is performed on the basis of the first check symbol sequence and the second check symbol sequence. It is thus possible to prevent deterioration of detection accuracy.

According to yet another embodiment, a decoding apparatus includes: an input unit to receive the code sequence including the third check symbol sequence from the encoding apparatus and input the received sequence when an encoding apparatus divides an information sequence into a plurality of groups, performs at least a portion of a block encoding process on a portion of the information sequence corresponding to each of the plurality of groups to generate a first code sequence for each group, performs the block encoding process on a first check symbol sequence in the first code sequence to generate a second code sequence for each group, combines a second check symbol sequence in the second code sequence with the portion of the information sequence so as to be associated with each other thereby generating a third code sequence for each group, combines the third code sequences in the plurality of groups, and performs the block encoding process on the combined third code sequence to generate a code sequence including a third check symbol sequence; an estimating unit to estimate the first code sequence for each group by performing the same block encoding process as that performed by the encoding apparatus to generate the first code sequence on a portion corresponding to the information sequence in the received sequence input by the input unit; a first processing unit to detect an error in the first check symbol sequence for each group on the basis of the first check symbol sequence in the first code sequence estimated by the estimating unit and a portion corresponding to the second check symbol sequence in the received sequence input by the input unit; a second processing unit to detect an error in the portion corresponding to the information sequence for each group on the basis of the first check symbol sequence whose error is detected by the first processing unit and the portion corresponding to the information sequence in the received sequence input by the input unit; and a third processing unit operative to correct the error in the portion corresponding to the information sequence on the basis of the portion corresponding to the information sequence whose error is detected by the second processing unit and portions corresponding to the second check symbol sequence and the third check symbol sequence in the received sequence input by the input unit.

Even when an information sequence is divided into a plurality of groups, a sequence is generated for each group so as not to include the first check symbol sequence. The generated sequence is received and input, the first check symbol sequence is estimated from the received sequence, and error detection is performed on the basis of the first check symbol sequence and the second check symbol sequence. It is therefore possible to prevent deterioration of detection accuracy.

When an error is detected from the first check symbol sequence, the first processing unit may correct the error and output the first check symbol sequence whose error is corrected to the second processing unit. When an error is detected from the portion corresponding to the information sequence, the second processing unit may correct the error. Since the error is detected and corrected, it is possible to improve reproduction characteristics.

The encoding apparatus may make combinations of the first check symbol sequences in the plurality of groups when the block encoding process for generating the second code sequence is performed different from each other according to the orders of the first check symbol sequences. The first processing unit may detect and correct the error using error detection information in the first check symbol sequences having different orders as erasure error information. It is thus possible to improve an error detection performance.

The third processing unit may perform erasure error correction as error correction while using the error detection information of each of the first code sequences as the erasure error information. Since the error detection information of each of the first code sequences is used as the erasure error information, it is possible to effectively perform error separation.

According to another embodiment, an encoding method includes: generating a first code sequence by performing at least a portion of a block encoding process on an input information sequence; generating a second code sequence by performing the block encoding process on a first check symbol sequence in the generated first code sequence; and generating a third code sequence by combining a second check symbol sequence in the generated second code sequence with the input information sequence.

According to another embodiment, an encoding method includes: dividing an input information sequence into a plurality of groups; generating a first code sequence for each group by performing at least a portion of a block encoding process on a portion of the information sequence corresponding to each of the plurality of divided groups; generating a second code sequence for each group by performing the block encoding process on a first check symbol sequence in the generated first code sequence; generating a third code sequence for each group by combining a second check symbol sequence in the generated second code sequence with the portion of the information sequence in each of the plurality of divided groups so as to be associated with each other; combining the generated third code sequences of the plurality of groups; and generating a fourth code sequence by performing the block encoding process on the combined third code sequence.

In generating the second code sequence for each group, combinations of the first check symbol sequences in the plurality of groups when the block encoding process is performed may be different from each other according to the order of the first check symbol sequence.

According to another embodiment, a decoding method includes: receiving the combined sequence of the second check symbol sequence in the second code sequence and the information sequence from the encoding apparatus and inputting the received sequence when an encoding apparatus performs at least a portion of a block encoding process on an information sequence to generate a first code sequence, performs the block encoding sequence on a first check symbol sequence in the first code sequence to generate a second code sequence, and combines a second check symbol sequence in the second code sequence with the information sequence; estimating the first code sequence by performing the same block encoding process as that performed by the encoding apparatus to generate the first code sequence on a portion corresponding to the information sequence in the received sequence; detecting an error in the first check symbol sequence on the basis of the first check symbol sequence in the estimated first code sequence and the second check symbol sequence in the received sequence; and detecting an error in the portion corresponding to the information sequence in the received sequence on the basis of the first check symbol sequence whose error is detected and the portion corresponding to the information sequence in the received sequence.

According to yet still another embodiment, a decoding method includes: receiving the code sequence including the third check symbol sequence from the encoding apparatus and inputting the received sequence when an encoding apparatus divides an information sequence into a plurality of groups, performs at least a portion of a block encoding process on a portion of the information sequence corresponding to each of the plurality of groups to generate a first code sequence for each group, performs the block encoding process on a first check symbol sequence in the first code sequence to generate a second code sequence for each group, combines a second check symbol sequence in the second code sequence with the portion of the information sequence so as to be associated with each other, thereby generating a third code sequence for each group, combines the third code sequences of the plurality of groups, and performs the block encoding process on the combined third code sequence to generate a code sequence including a third check symbol sequence; estimating the first code sequence for each group by performing the same block encoding process as that performed by the encoding apparatus to generate the first code sequence on a portion corresponding to the information sequence in the received sequence; detecting an error in the first check symbol sequence for each group, on the basis of the first check symbol sequence in the estimated first code sequence and a portion corresponding to the second check symbol sequence in the received sequence; detecting an error in the portion corresponding to the information sequence on the basis of the first check symbol sequence whose error is detected and the portion corresponding to the information sequence in the received sequence; and correcting the error in the portion corresponding to the information sequence, on the basis of the portion corresponding to the information sequence whose error is detected and portions corresponding to the second check symbol sequence and the third check symbol sequence in the received sequence.

In correcting the error in the portion corresponding to the information sequence, erasure error correction may be performed as the error correction while using error detection information of each of the first code sequences as erasure error information.

### BRIEF DESCRIPTION OF THE DRAWINGS

FIG. 1 is a diagram illustrating the structure of a recording apparatus according to a first embodiment;

FIG. 2 is a diagram illustrating the structure of data input to a dividing unit as shown in FIG. 1;

FIG. 3 is a diagram illustrating the structure of a code sequence generated by a first encoding unit and a second encoding unit as shown in FIG. 1;

FIG. 4 is a diagram illustrating the structure of a code sequence generated by a generating unit and a combining unit as shown in FIG. 1;

FIG. 5 is a diagram illustrating the structure of a code sequence generated by a third encoding unit as shown in FIG. 1;

FIG. 6 is a diagram illustrating the structure of a frame generated by a format unit as shown in FIG. 1;

FIG. 7 is a diagram illustrating the structure of a reproducing apparatus according to the first embodiment;

FIG. 8 is a diagram illustrating the outline of an operation of using a CRC code to correct an erasure pointer, which is a comparative example of the operation of the reproducing apparatus shown in FIG. 7;

FIG. 9 is a diagram illustrating the outline of an erasure pointer correcting operation of the third processing unit as shown in FIG. 7;

FIG. 10 is a flowchart illustrating an encoding process of the recording apparatus as shown in FIG. 1;

FIG. 11 is a flowchart illustrating a decoding process of the reproducing apparatus as shown in FIG. 7;

FIG. 12 is a diagram illustrating the structure of a partial encoding unit according to a second embodiment;

FIG. 13 is a diagram illustrating the structure of a code sequence generated by a first encoding unit as shown in FIG. 12;

FIG. 14 is a diagram illustrating a changing rule of a changing unit as shown in FIG. 12;

FIG. 15 is a diagram illustrating another changing rule of the changing unit as shown in FIG. 12;

FIG. 16 is a diagram illustrating the structure of a partial decoding unit according to the second embodiment; and

FIG. 17 is a flowchart illustrating an encoding process according to the second embodiment.

### DETAILED DESCRIPTION

### First Embodiment

A first embodiment relates to a recording apparatus that performs RS encoding on data of 64 kbytes or more to record the data on a recording medium and a reproducing apparatus that performs RS decoding on data recorded on a recording medium to reproduce the data.

When 2⁸ Galois fields are defined as an RS code, the maximum code length of the RS code is 2⁸−1. The recording apparatus arranges data in a two-dimensional array (a “first array”). The first array has one side with a length that is equal to or smaller than the maximum code length. The other side has a length that is larger than the maximum code length. For example, one side corresponds to a column component and the other side corresponds to a row component.

The recording apparatus extracts one row component from the first array and arranges the row components in a two-dimensional array (a “second array”). The second array has two sides with a length that is equal to or smaller than the maximum code length. The recording apparatus further generates a product code for the second array. The generated product code includes the above-mentioned P, Q, and R parities.

The recording apparatus removes the parities P and Q, and leaves only the parity R. The recording apparatus adds the parity R to the rear of the row component and returns to the first array. The length of the row component in the first array is thus increased by a value corresponding to the parity R (which may also be referred to as a “first array”). The above-mentioned processes are performed on each column component. The recording apparatus performs RS encoding on each row component in the first array. As a result, parities S and T are generated.

The reproducing apparatus performs reverse processes of the recording apparatus. The reproducing apparatus performs RS encoding on data arranged in the second array to estimate at least one of the parities P and Q. In this embodiment, the reproducing apparatus estimates the parity Q. The reproducing apparatus performs syndrome calculation on the parities Q and R to detect the error of the parity Q. In addition, the reproducing apparatus performs syndrome calculation on data and the parity Q whose errors are detected to detect the error of the data. Further, the reproducing apparatus returns the data whose error is detected to the first array and uses the parities S and T to perform syndrome calculation thereby correcting the error of the data.

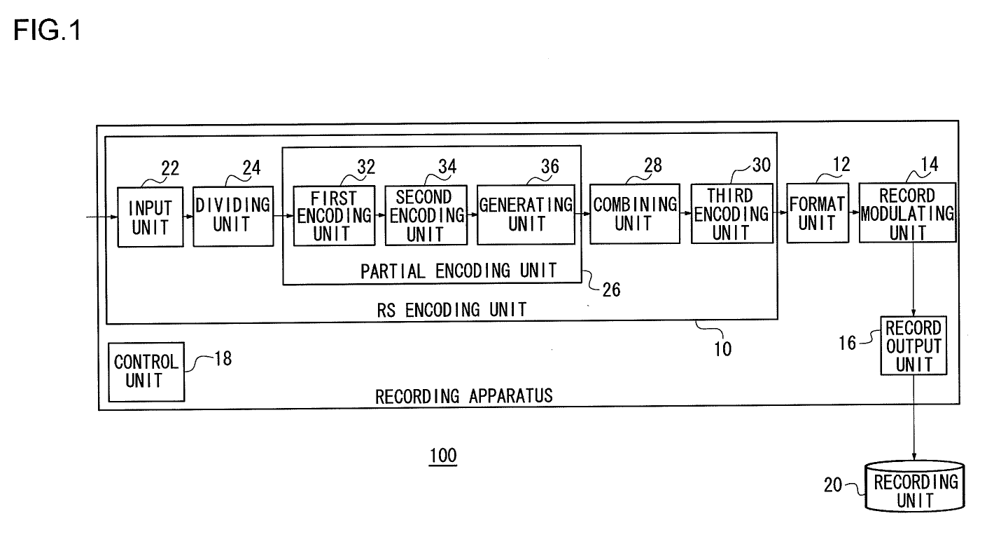

FIG. 1 is a diagram illustrating the structure of a recording apparatus 100 according to the first embodiment. The recording apparatus 100 includes an RS encoding unit 10, a format unit 12, a record modulating unit 14, a record output unit 16, a control unit 18, and a recording unit 20. The RS encoding unit 10 includes an input unit 22, a dividing unit 24, a partial encoding unit 26, a combining unit 28, and a third encoding unit 30. The partial encoding unit 26 includes a first encoding unit 32, a second encoding unit 34, and a generating unit 36. The input unit 22 inputs data to be recorded in the recording apparatus 100—data to be subjected to RS encoding. In this embodiment, data is processed in the unit of 64 kbytes. The dividing unit 24 receives data from the input unit 22.

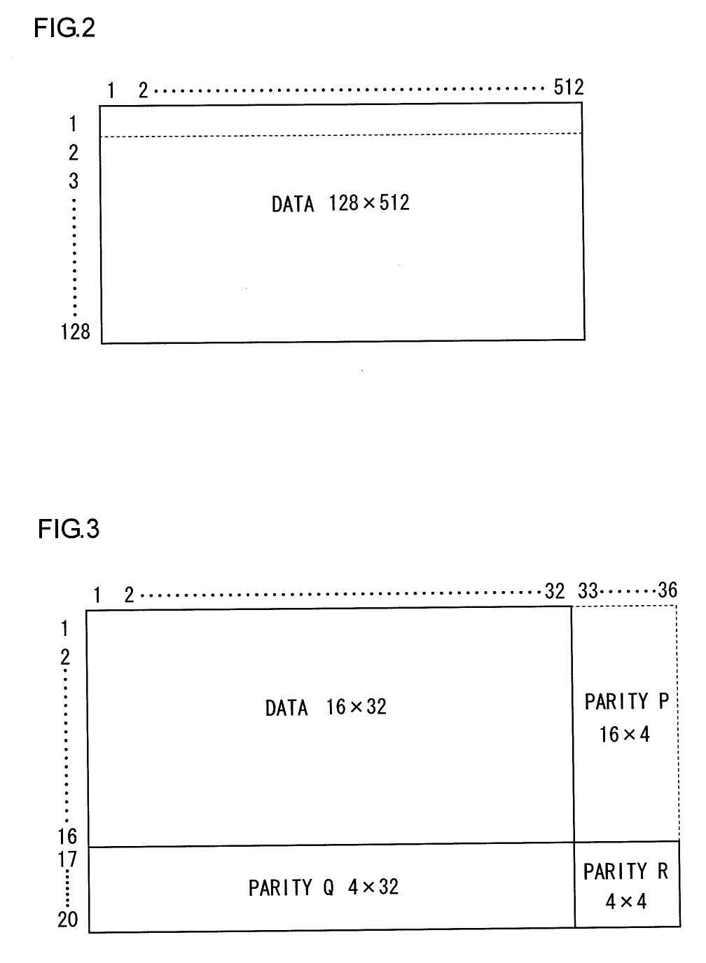

FIG. 2 is a diagram illustrating the structure of data input to the dividing unit 24. In FIG. 2, 64-kbyte data are arranged in a matrix of 512×128 bytes. This arrangement corresponds to a first array of 128 rows by 512 columns. In the first array, it is possible to generate an RS code sequence with 2⁸ Galois fields in the vertical direction of 128 bytes—a column component—but it is difficult to generate an RS code sequence in the horizontal direction of 512 bytes—a row component. The first array is formed by a two-dimensional array including a row with a length that is larger than the maximum code length of RS encoding and a column with a length that is smaller than the maximum code length.

Referring again to FIG. 1, the dividing unit 24 divides the first array into a plurality of groups to generate a plurality of second arrays. Specifically, the dividing unit 24 extracts data corresponding to one row of the first array shown in FIG. 2, and performs division such that data corresponding to one row is one group. The one group corresponds to one second array. The above-mentioned process is performed on each row of the first array.

FIG. 3 is a diagram illustrating the structure of a code sequence generated by the first encoding unit 32 and the second encoding unit 34. In this embodiment, among data shown in FIG. 3, only data generated by the dividing unit 24 will be described. One row shown in FIG. 2 has 512 bytes. As shown in FIG. 2, the dividing unit 24 arranges 512-byte data in a matrix of 16 bytes by 32 bytes.

Referring again to FIG. 1, the first encoding unit 32 performs at least a portion of the RS encoding process defined by product code on data corresponding to each of the plurality of second arrays divided by the dividing unit 24 to generate a first code sequence for each second array. The product code includes RS encoding in the row direction of the second array and RS encoding in the column direction of the second array. The parity P is generated by the RS encoding in the row direction; the parity Q is generated by the RS encoding in the column direction. Since the first encoding unit 32 performs only the RS encoding in the column direction of the second array, the first code sequence includes only the parity Q.

The primitive polynomial of the Galois field is represented by Expression 1 given below:

α⁸α⁴α³α²+1=0 [Expression 1]

In addition, the generating polynomial of the first code sequence is represented by Expression 2 given below:

$$g ( x ) = {\prod }_{i = 0}^{3} ( x + {α}^{i} ) \qquad [ Expression 2 ]$$

When the parities Q generated in first, i-th, and 32nd columns in FIG. 3 are q₀(x), qᵢ(x), and q₃₁(x), the parities are represented by Expression 3 given below:

q₀(x)=q₀₃x³+q₀₂x²+q₀₁x+q₀₀

qᵢ(x)=qᵢ₃x³+qᵢ₂x²+qᵢ₁x+qᵢ₀

q₃₁(x)=q₃₁₃x³+q₃₁₂x²+q₃₁₁x+q₃₁₀ [Expression 3]

The same parity P may be generated. As described above, however, in this embodiment since the generation of the parity P is omitted, a description thereof will not be repeated.

The first code sequence output from the first encoding unit 32 is input to the second encoding unit 34. The second encoding unit 34 performs RS encoding on the parity Q in the first code sequence to generate a second code sequence for each second array. Specifically, the second encoding unit 34 uses the above-mentioned generating polynomial for rows having the parity Q—a set of parities having the same dimension; for example, q₀₃(x), q₁₃(x), . . . q₁₃(x), . . . q₃ᵢ₃(x) to generate the parities R of the rows. In addition, the second encoding unit 34 performs the same process as described above on rows having parities other than the parity Q to generate the parities R. In the parities R, a component r₃(x) corresponding to one row is represented by Expression 4 given below:

r₃(x)=r₃₃x³+r₃₂x²+r₃₁x+r₃₀ [Expression 4]

In addition, components r₂(x), r₁(x), and r₀(x) corresponding to the other rows are similarly represented.

FIG. 3 is a diagram illustrating the structure of the code sequence generated by the first encoding unit 32 and the second encoding unit 34. In the code sequence, data has already been described. In the columns having data arranged therein, the parities Q are arranged from a 17th row to a 20th row. The parities Q include 4×32 components. In addition, the parities R are arranged from the 17th row to the 20th row and from a 33rd column to a 36th column. The parities R include 4×4 components. In the rows having data arranged therein, the parities P may be arranged from the 33rd column to the 36th column. As described above, a description thereof will not be repeated.

Referring again to FIG. 1, the generating unit 36 combines the parity R in the second code sequence generated by the second encoding unit 34 with data in the second array so as to be associated with each other, thereby generating a third code sequence for each group. In this case, the third code sequence includes only data and the parity R. As described above, since data in the second array corresponds to one row of the first array, the generating unit 36 extends the length of each row in the first array to combine the parity and data such that the third code sequence is included in one row. That is, the generating unit 36 discards the parity Q, and uses data and the parity R to generate one row of the first array. In addition, a plurality of third code sequences is generated to correspond to a plurality of second arrays.

The combining unit 28 combines the plurality of third code sequences generated by the generating unit 36. As a result, a two-dimensional array (as described above, this may also be referred to as a “first array”) having row components with a length that is larger than that of the first array is generated.

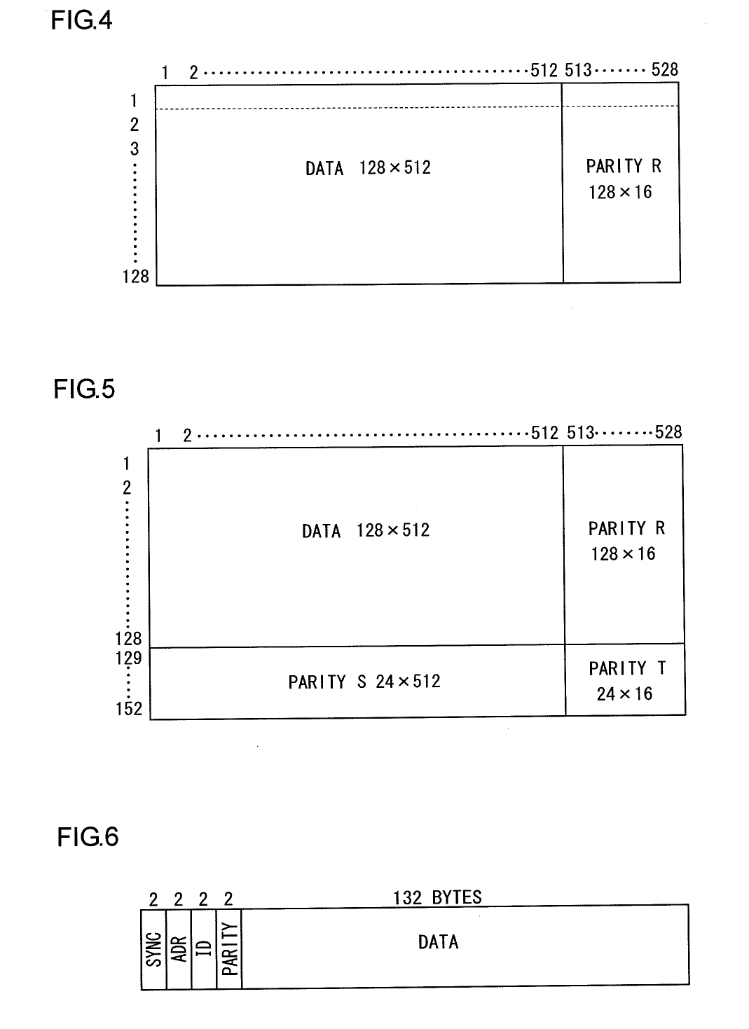

FIG. 4 is a diagram illustrating the structure of a code sequence generated by the generating unit 36 and the combining unit 28. The structure of data is the same as that shown in FIG. 2. The parities R are arranged from a 513th column to a 528th column. The parities R include 128×16 components.

Referring again to FIG. 1, the third encoding unit 30 performs RS encoding on each column of the first array generated by the combining unit 28. Specifically, a generating polynomial is represented by Expression 5 given below:

$$g ( x ) = {\prod }_{i = 0}^{23} ( x + {α}^{i} ) \qquad [ Expression 5 ]$$

The third encoding unit 30 performs RS encoding on each column of data in the first array and each row of the parities R in the first array to generate a fourth code sequence including the parities S and T.

FIG. 5 is a diagram illustrating the structure of a code sequence generated by the third encoding unit 30. The structures of data and the parity R are the same as those shown in FIG. 4. In the columns having data arranged therein, the parities S are arranged from a 129th row to a 152nd row. The parities S include 24×512 components. In the columns having the parities R arranged therein, the parities T are arranged from the 129th row to the 152nd row.

Referring again to FIG. 1, the format unit 12 divides data in the fourth code sequence into 132-byte data components and stores the data components in different frames. In addition, a synchronization signal (SYNC), an address (ADR), an identification (ID) number, and a parity are added to each frame.

FIG. 6 is a diagram illustrating the structure of the frame generated by the format unit 12. The SYNC, the ADR, the ID number, a parity, and data are arranged from the head of the frame, and include 2 bytes, 2 bytes, 2 bytes, 2 bytes, and 132 bytes, respectively.

Referring again to FIG. 1, the record modulating unit 14 receives a plurality of frames from the format unit 12. The record modulating unit 14 performs, for example, 8-16 modulation. Known 8-16 modulation techniques may be used and thus a description thereof is omitted. The record modulating unit 14 may perform modulations other than the 8-16 modulation according to the kind of recording unit 20 (i.e. the kind of recording mediums). The record output unit 16 receives the modulation result from the record modulating unit 14 and records the modulation result on the recording unit 20. The recording unit 20 is composed of a recording medium, such as a Blu-ray disk (BD), a digital versatile disk (DVD), a compact disc (CD), a hard disk (HD), a silicon disk (SD), or memory. The demodulation result is recorded on the recording unit. The recording unit 20 may be fixed to, removable from, or connected to the recording apparatus 100 wirelessly or by wire. The control unit 18 controls the overall operation of the recording apparatus 100.

This structure may be implemented by an LSI, memory, or a CPU of a computer in a hardware manner. This structure may also be implemented by a program loaded to the memory in a software manner. Functional blocks are implemented by a combination of the hardware and software manners. Therefore, it will be understood by those skilled in the art that the functional blocks may be implemented by only hardware, only software, or a combination thereof.

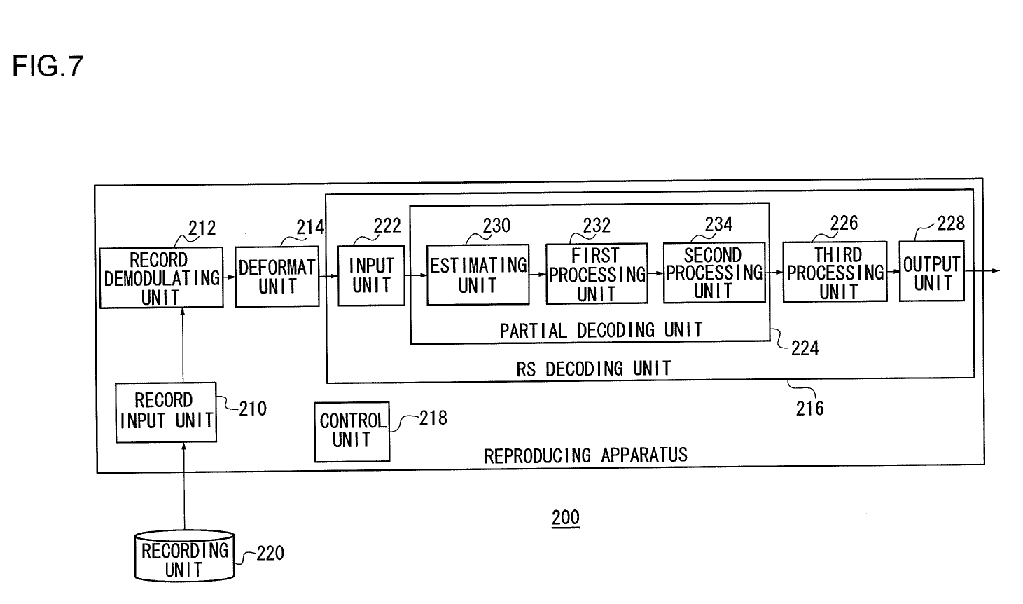

FIG. 7 is a diagram illustrating the structure of a reproducing apparatus 200 according to the first embodiment. The reproducing apparatus 200 includes a record input unit 210, a record demodulating unit 212, a deformat unit 214, an RS decoding unit 216, a control unit 218, and a recording unit 220. The RS decoding unit 216 includes an input unit 222, a partial decoding unit 224, a third processing unit 226, and an output unit 228. The partial decoding unit 224 includes an estimating unit 230, a first processing unit 232, and a second processing unit 234.

The recording unit 220 corresponds to the recording unit 20 shown in FIG. 1. The recording unit 220 may be the same as or different from the recording unit 20. The record input unit 210 reads out a signal from the recording unit 220. The read signal corresponds to the above-mentioned modulation result. The record demodulating unit 212 receives the modulation result from the record input unit 210 and demodulates the modulation result. In addition, the record demodulating unit 212 performs demodulation corresponding to the modulation scheme of the record modulating unit 14 shown in FIG. 1. The deformat unit 214 receives the demodulation result from the record demodulating unit 212, detects the SYNC shown in FIG. 6, and generates the first array shown in FIG. 5 on the basis of the ADR.

The input unit 222 receives the first array from the deformat unit 214. The first array is also called a received sequence. The input unit 222 divides the first array into rows and outputs components included in each row to the estimating unit 230. The estimating unit 230 receives the components included in each row from the input unit 222. The estimating unit 230 and the first and second processing units 232 and 234 process the components included in each row. For clarity of description, however, processes performed on the components included in one row will be described below. Components included in the other rows are similarly processed.

The estimating unit 230 performs the same RS encoding process as that for generating the first code sequence in the first encoding unit 32 of the recording apparatus 100 (not shown) on components corresponding to data among the components included in one row, thereby estimating the first code sequence. As described above, since the recording apparatus 100 (not shown) deletes the generated parity Q, the parity Q is not included in the received sequence. Therefore, the estimating unit 230 generates the parity Q from a portion corresponding to data.

The first processing unit 232 performs syndrome calculation on the parity Q in the first code sequence estimated by the estimating unit 230 and components corresponding to the parity R among the components included in one row output from the input unit 222. As a result, the error of the parity Q is detected. In this case, the second array shown in FIG. 3 is formed and the syndrome calculation is performed on 17th to 20th rows of the second array, respectively.

In addition, during the syndrome calculation, the generating polynomial of the first code sequence in the first encoding unit 32 is used. If all the syndromes are “0”, there is no error in the corresponding row. If all the syndromes are not “0”, however, the first processing unit 232 detects the error of the row and corrects the error. In this case, an error of 2 bytes or less can be corrected. When the error correction is unavailable, that is, when there is an error of 3 bytes or more, the first processing unit 232 regards the entire row as an error and places an erasure pointer in the row. The first processing unit 232 outputs any one of the parity Q to be checked that it has no error, the parity Q whose error is corrected, and the parity Q having an erasure pointer placed therein to the second processing unit 234.

The second processing unit 234 receives the parity Q from the first processing unit 232. The second processing unit 234 performs syndrome calculation on the parity Q output from the first processing unit 232 and components corresponding to data among the components included in one row output from the input unit 222. As a result, the errors of the components corresponding to data are detected. In this case, the syndrome calculation is performed on 1st to 32nd columns of the second array. In addition, during the syndrome calculation, the generating polynomial of the first code sequence in the first encoding unit 32 is used. If a syndrome is “0”, there is no error in the corresponding column.

If the syndrome is not “0”, however, the second processing unit 234 detects the error of the column, and corrects the error. In this case, an error of 2 bytes or less can be corrected. When the error correction is unavailable, that is, when there is an error of 3 bytes or more, the second processing unit 234 regards the entire column as an error and places an erasure pointer in the column. This process narrows down a position including an error. In this embodiment, erasure pointers can be placed in arbitrary two columns having errors. The second processing unit 234 outputs any one of a portion corresponding to data to be checked that it has no error, a portion corresponding to data whose error is corrected, and a portion corresponding to data having an erasure pointer placed therein to the third processing unit 226.

The third processing unit 226 receives a portion corresponding to data from the second processing unit 234, and generates the first array shown in FIG. 5. The third processing unit 226 performs syndrome calculation on a portion corresponding to data in the first array and the parities R, S, and T. As a result, the error of the portion corresponding to data is corrected. In this case, the syndrome calculation is performed on each column of the first array. The generating polynomial of the third code sequence in the third encoding unit 30 is used for the syndrome calculation. The third processing unit 226 corrects the portion corresponding to data on the basis of the syndrome calculation results and erasure pointer information.

FIG. 8 is a diagram illustrating the outline of an operation of using a CRC code to correct an erasure pointer, which is a comparative example of the reproducing apparatus 200. The structure shown in FIG. 8 is the same as that shown in FIG. 5. In FIG. 8, a dashed line corresponds to a row having an error. That is, the dashed line corresponds to a row having an erasure pointer placed therein. In the related art, the CRC code is used to process data of 256 bytes or more. In this case, as shown in FIG. 8, it is assumed that all data components in one row have errors.

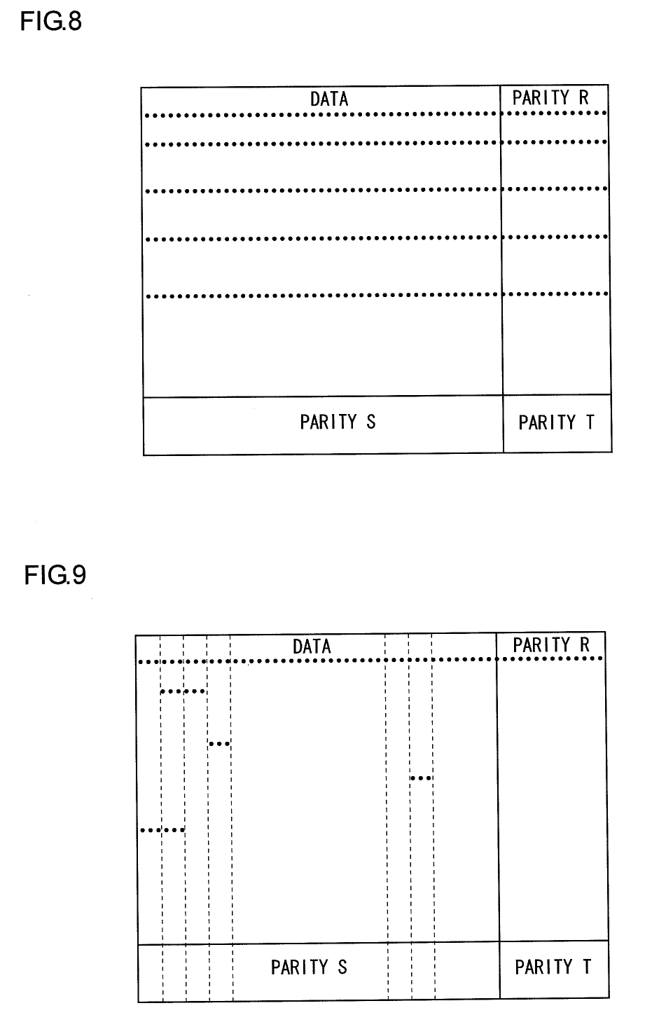

FIG. 9 is a diagram illustrating the outline of the operation of the third processing unit 226 correcting the erasure pointer. The error range is limited to 16 bytes by the processes of the first processing unit 232 and the second processing unit 234 performed on the second array. As a result, the overlap of an error row generating the parity S is reduced and the correction performance of the third processing unit 226 is improved.

A pointer erasure method of correcting errors while using error detection information for each first code sequence as an erasure pointer is performed. The performance of the above-mentioned operation greatly depends on the reproduction error of a second check symbol sequence. Therefore, it is possible to improve a correction performance by detecting and correcting the error of the second check symbol sequence with the fourth code sequence and performing the above-mentioned operation from the beginning. Referring to again FIG. 1 again, the output unit 228 receives data whose error is corrected from the third processing unit 226 and outputs the received data as reproduction data. The control unit 218 controls the overall operation of the reproducing apparatus 200.

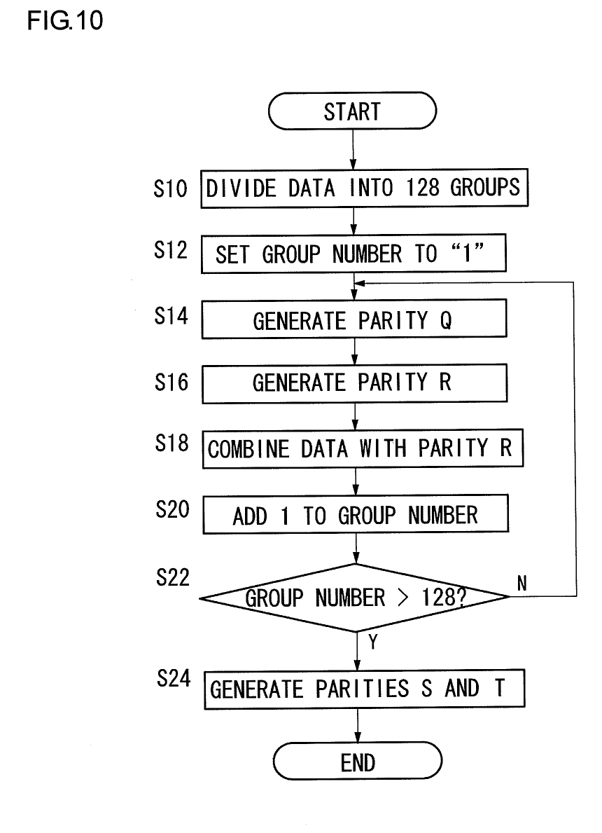

The operation of the recording apparatus 100 having the above-mentioned structure is now described. FIG. 10 is a flowchart illustrating an encoding process of the recording apparatus 100. The dividing unit 24 divides data into 128 groups (S10). The first encoding unit 32 sets a group number to “1” (S12). The first encoding unit 32 calculates the parity Q (S14). The second encoding unit 34 calculates the parity R (S16). The generating unit 36 combines data with the parity R (S18). The first encoding unit 32 adds 1 to the group number (S20).

If the group number is smaller than 128 (S22: N), the process returns to step 14. If the group number is larger than 128 (S22: Y), the combining unit 28 combines data and the parity R in each group. The third encoding unit 30 calculates the parities S and T (S24).

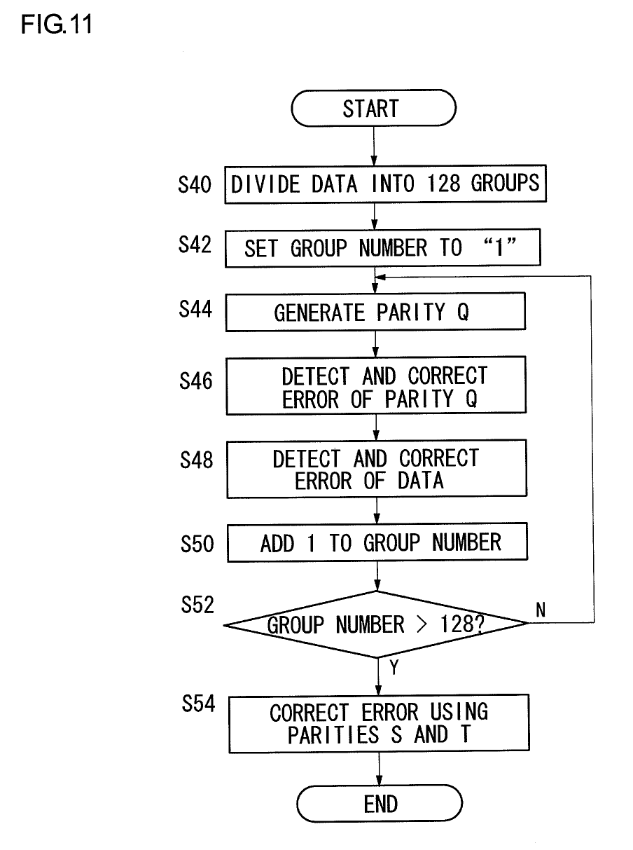

The operation of the reproducing apparatus 200 having the above-mentioned structure will be described. FIG. 11 is a flowchart illustrating a decoding process of the reproducing apparatus 200. The input unit 222 divides data into 128 groups (S40). The estimating unit 230 sets a group number to “1” (S42). The estimating unit 230 generates the parity Q (S44). The first processing unit 232 detects and corrects the error of the parity Q (S46). The second processing unit 234 detects and corrects the error of a portion corresponding to data (S48). The estimating unit 230 adds 1 to the group number (S50).

If the group number is smaller than 128 (S52: N), the process returns to step 44. If the group number is larger than 128 (S52: Y), the third processing unit 226 uses the parities S and T to perform error correction (S54).

Data is divided into a plurality of groups and a third code sequence without the parity Q is generated for each group. It is thus possible to improve transmission efficiency. Also, after RS encoding is performed on the second array, RS encoding is performed in the direction of the first array having a length that is equal to or smaller than the maximum code length. Therefore, it is possible to perform RS encoding even when data has a large size. The first array is also divided such that data corresponding to one row forms one group. Therefore, even when data has a size that is larger than the maximum code length, RS encoding can be performed on the data. Further, even when a received sequence that is generated for each group so as not to include the parity Q is input after data is divided into a plurality of groups, the parity Q is estimated from the received sequence, and error detection is performed on the basis of the parities Q and R. Therefore, it is possible to decode a code sequence generated by block encoding with improved transmission efficiency and prevent the deterioration of detection accuracy. Since both error detection and error correction are performed, it is also possible to improve reproduction characteristics.

Since the parity Q is not transmitted and recorded, it is possible to reduce redundancy and improve transmission efficiency. Also, it is possible to narrow down an error range, as compared to a structure in which a CRCC is added as an error detection code in the row direction. Therefore, it is possible to improve a correction performance of outer codes. Also, it is possible to treat data having a length that is larger than the maximum code length of an RS code defined by the Galois field, and performs the generation and correction of codes using a small circuit. Further, since an outer code is added, it is possible to improve a correction performance using a small circuit. Furthermore, since the error range is limited to 16 bytes, it is possible to reduce the overlap of an error row generating the parity S and improve a correction performance.

### Second Embodiment

In the first embodiment, the parity R is used to detect the error of a 16-byte column parity. As described above, the parities R are arranged in 4 rows. Since 4 rows of the parities all detect the error of the same column, however, the parities are redundantly used to detect the error of a column. Therefore, in a second embodiment, 4 rows of parities detect errors of different columns in order to improve the efficiency of parity and an error correction performance. In the second embodiment, a recording apparatus generates parities Q, and combines the parities with different orders for each of four groups to generate parities R.

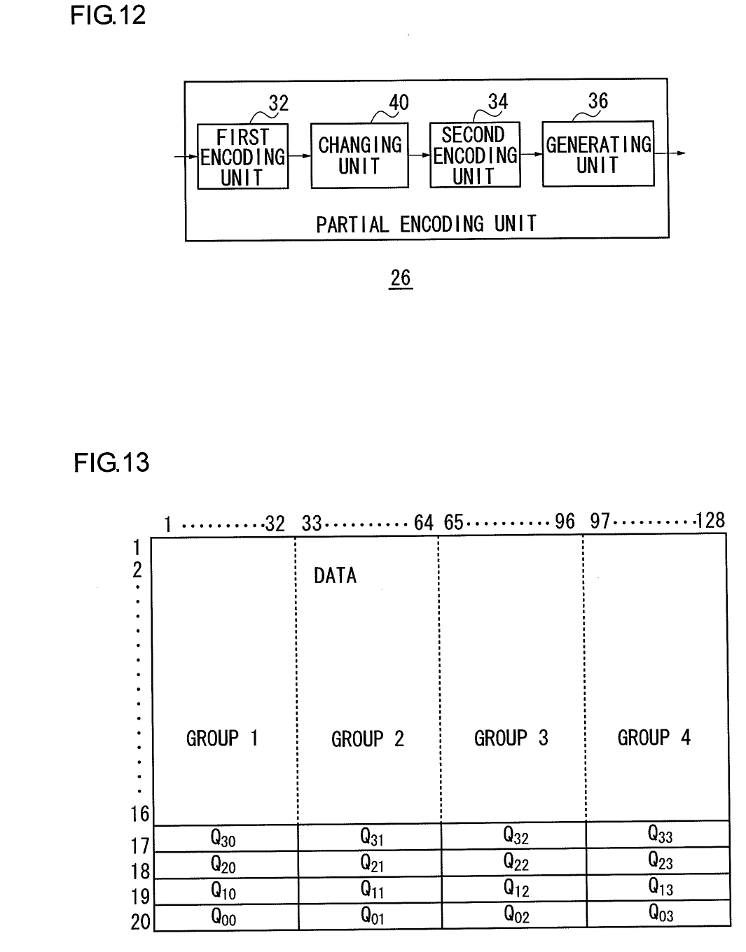

FIG. 12 is a diagram illustrating the structure of a partial encoding unit 26 according to the second embodiment. The partial encoding unit 26 includes a first encoding unit 32, a changing unit 40, a second encoding unit 34, and a generating unit 36. As described above, the first encoding unit 32 generates a first code sequence.

FIG. 13 is a diagram illustrating the structure of a code sequence generated by the first encoding unit 32. FIG. 13 shows data and parities Q for four groups. The four groups include 1st to 32nd columns (“group 1”), 33rd to 64th columns (“group 2”), 65th to 96th columns (“group 3”), and 97th to 128th columns (“group 4”). Since each of the groups corresponds to one row of the first array shown in FIG. 4, four rows are extracted from the first array shown in FIG. 4 to generate the code sequence shown in FIG. 13. The parities Q included in the group 1 are represented by Q₃₀, Q₂₀, Q₁₀, and Q₀₀. This is similarly applied to the groups 2 to 4.

Referring to FIG. 12 again, the changing unit 40 changes combinations of the parities Q (“parities Q”) in the first code sequence generated by the first encoding unit 32 for 4 groups.

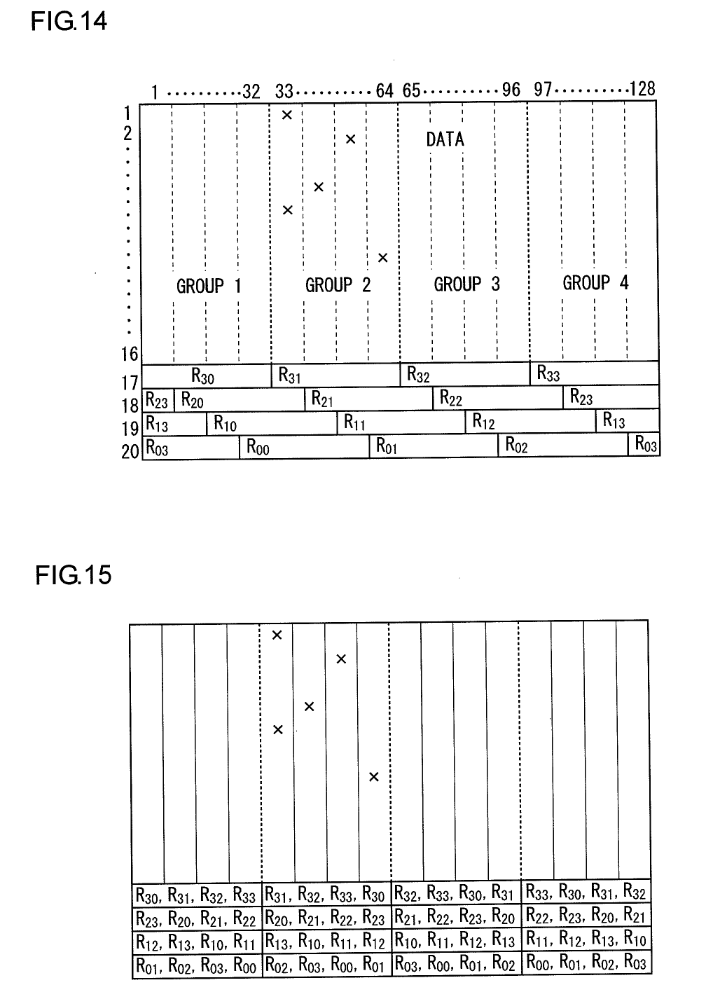

FIG. 14 shows a conversion rule of the changing unit 40. FIG. 14 shows the combined groups 1 to 4, similar to FIG. 13. In FIG. 14, a combination of the parities Q for generating the parity R is changed for each row. Specifically, in a 17th row, a combination of the parities Q for changing the parity R is not changed. For example, the parity Q₃₀ is used without any change in order to generate a parity R₃₀. In an 18th row, a combination for generating the parity R such that the parity Q is shifted to the right side by 8 columns, that is, in a direction in which the column number is increased is defined. For example, the parities Q in 9th to 40th columns are used to generate a parity R₂₀. In the 19th and 20th rows, combinations for generating the parities R that the parity Q is shifted to the right side by 16 columns and 24 columns are defined, respectively. That is, a combination for generating the parity R is changed depending on the order of each parity Q.

FIG. 15 is a diagram illustrating another changing rule of the changing unit 40.In FIG. 15, components of four groups are mixed in one group. Therefore, the components are uniformly grouped.

Referring again to FIG. 12, the second encoding unit 34 performs RS encoding on the parities Q changed by the changing unit 40. For example, the second encoding unit 34 generates the parity R₂₀ on the basis of the parities Q included in the parity R₂₀ shown in FIG. 14. The generated code sequence is also referred to as the second code sequence. The processes of the second encoding unit 34 and the generating unit 36 are the same as those in the first embodiment and a description thereof is not repeated.

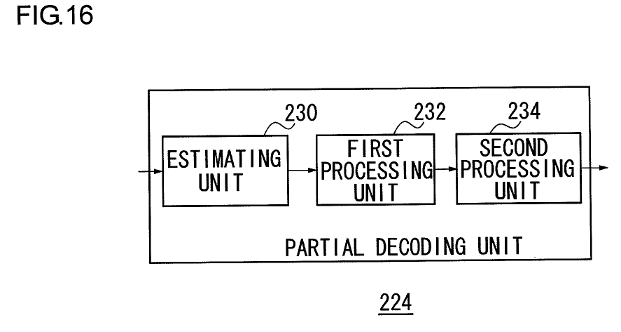

FIG. 16 is a diagram illustrating the structure of a partial decoding unit 224 according to the second embodiment of the present invention. The partial decoding unit 224 includes an estimating unit 230, a first processing unit 232, and a second processing unit 234. The process of the estimating unit 230 is the same as that in the first embodiment.

The first processing unit 232 performs syndrome calculation on the parity Q in the first code sequence estimated by the estimating unit 230 and components corresponding to the parity R among the components included in one row output from the input unit 22. The first processing unit 232 corrects a maximum of two errors on the basis of 16 sets of reproduced parities R. When the parity R has two or more errors, or an unspecified number of errors, the first processing unit 232 uses error correction information of another parity to correct an erasure pointer. In this way, a maximum of four error columns are specified.

In FIG. 14, error points are represented by “x”. A set of the parities R₃₁ and a set of the parities R₂₁ have five errors and three errors, respectively. Therefore, the error points are not specified. Since a set of the parities R₁₁ has two errors, however, a column including the error is specified. An erasure pointer is placed in the column having the error to specify one error column in the set of the parities R₂₁. Similarly, since errors are included in only two columns in a set of the parities R₂₀, the error columns are specified. As a result, five error columns included in the second row of the first array are specified.

The above-mentioned process is now described in detail. First, the parity R₃₀ is calculated, and then the parity R₂₀ is calculated. The parities each have two errors, and it is possible to correct the errors. The error column of the parity R₂₀ is added to the parity R₁₀ and then calculation is performed. In this case, since there is one error, it is possible to correct the error. The error columns of the parities R₂₀ and R₁₀ are added to the parity R₀₀, and then calculation is performed. In this case, since there is one error, it is difficult to specify an error column. Then, the syndrome of the parity R₃₁ is calculated. In the parity R₃₁, it has been checked that there are four errors, and the last one error is not specified. Then, the syndrome of the parity R₂₁ is calculated. In this parity, it is also difficult to specify an error column. Then, the syndrome of the parity R₁₁ is calculated. In this case, it is possible to correct two errors. The error column of the parity R₁₁ is added to the parity R₀₁, and then calculation is performed. The above-mentioned processes are repeatedly performed. Since there is no error in FIG. 14, a description thereof will not be repeated

Since there is no additional error in the parity R₀₁, it is possible to verify whether the error of the parity R₁₁ is correct. If the error of the parity R₁₁ is correct, it is estimated that one error of the parity R₁₁ is correct. The error column of the parity R₁₁ is added to the parity R₂₁ and then calculation is performed again. If newly detected error columns are the same as those of the parity R₁₀, it is estimated that all the detected error columns are correct. Then, syndrome calculation is performed on the parity R₀₀ again. As a result, the errors of all the error columns and the errors other than the error of the parity R₃₁ are corrected. That is, the first processing unit 232 detects and corrects the errors using error detection information in the first check symbol sequences having different orders as an erasure pointer. The error columns of the parity R₃₁ are specified, but are not corrected since there are five errors. In this case, the second processing unit 234 processes the parities Q included in the parity R₃₁. If there is a data error in each column and it is verified that there is an error in the parity R₃₁, it is estimated that all the correcting operations are correct.

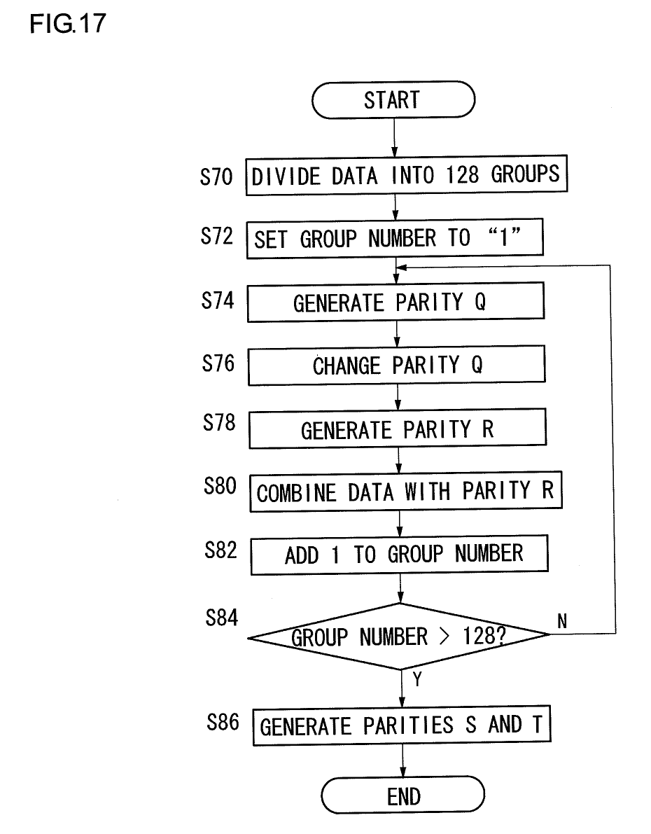

FIG. 17 is a flowchart illustrating an encoding process according to the second embodiment of the present invention. The dividing unit 24 divides data into 128 groups (S70). The first encoding unit 32 sets a group number to “1” (S72). The first encoding unit 32 calculates the parity Q (S74). The changing unit 40 changes the parity Q (S76). The second encoding unit 34 calculates the parity R (S78). The generating unit 36 combines data with the parity R (S80). The first encoding unit 32 adds 1 to the group number (S82).

If the group number is smaller than 128 (S84: N), the process returns to Step 74. If the group number is larger than 128 (S84: Y), the combining unit 28 combines data and the parity R between the groups. The third encoding unit 30 calculates the parities S and T (S86).

According to this embodiment, a combination of the parities Q for generating the parity R varies depending on the order of the parity Q. It is thus possible to improve an error detection performance. Also, since a combination of the parities Q for generating the parity R varies depending on the order of the parity Q and error points are subdivided, it is possible to reduce the overlap between errors. And since the overlap between the errors is reduced, it is possible to improve an outer code correction performance.

The present invention has been described above with reference to the exemplary embodiments. The above-described embodiments are illustrative and will be understood by those skilled in the art that various modifications of the above-mentioned components or processes can be made and the modifications are also included in the scope of the present invention. Combinations of the above-mentioned components are included in the scope of the present invention, and modifications of an apparatus, a method, a system, a recording medium, and a computer program may also be included in the scope of the invention.

For example, in the first and second embodiments of the present invention, the dividing unit 24 divides the first array into a plurality of second arrays, and the partial encoding unit 26 performs RS encoding on each of the second arrays. The present invention is not limited thereto; for example, when the size of data to be processed by the recording apparatus 100 is small, the partial encoding unit 26 may perform RS encoding on data arranged in the second array without providing the dividing unit 24.

In this case, the input unit 22 provides input of the data. The first encoding unit 32 arranges data in the second array, and performs at least a portion of the RS encoding process defined by a product code to generate a first code sequence. The second encoding unit 34 performs RS encoding on the parity Q in the first code sequence generated by the first encoding unit 32 to generate a second code sequence. The generating unit 36 combines data and the parity R in the second code sequence generated by the data second encoding unit 34 to generate a third code sequence.

The reproducing apparatus 200 performs an operation corresponding to the recording apparatus 100. The estimating unit 230 performs the same RS encoding process as that for generating the first code sequence on a portion corresponding to data included in the received sequence to estimate the first code sequence. Of the parity Q in the first code sequence estimated by the estimating unit 230 and a portion corresponding to the parity R in the received sequence, the first processing unit 232 detects the error of the parity Q.

Of the parity Q whose error is detected by the first processing unit 232 and a portion corresponding to data in the received sequence, the second processing unit 234 detects the error of the portion corresponding to data. According to this modification, since the third code sequence without the parity Q is generated, it is possible to improve transmission efficiency during RS encoding. Also, even when a received sequence without the parity Q is input, the parity Q is estimated from the received sequence, and error detection is performed on the basis of the parity Q and the parity R. Therefore, it is possible to prevent deterioration of detection accuracy.

With reference to a further modification, in the first and second embodiments of the present invention, the recording apparatus 100 and the reproducing apparatus 200 use RS encoding as block encoding; the present invention is not limited thereto. For example, the recording apparatus 100 and the reproducing apparatus 200 may use block encoding other than RS encoding. For example, the recording apparatus 100 and the reproducing apparatus 200 may use BCH encoding. According to this modification, the present invention can be applied to various block encoding processes.

What is claimed is:

1. An encoding apparatus, the apparatus comprising:
an input unit for receiving an information sequence;
a first encoding unit for generating a first code sequence by performing at least a portion of a block encoding process on the information sequence received by the input unit;
a second encoding unit for generating a second code sequence by performing the block encoding process on a first check symbol sequence in the first code sequence generated by the first encoding unit; and
a generating unit for generating a third code sequence by combining a second check symbol sequence in the second code sequence generated by the second encoding unit with the information sequence received by the input unit.

2. An encoding apparatus, the apparatus comprising:
an input unit for receiving an information sequence;
a dividing unit for dividing the information sequence into a plurality of groups;
a first encoding unit for generating a first code sequence for each group by performing at least a portion of a block encoding process on a portion of the information sequence corresponding to each of the plurality of groups divided by the dividing unit;
a second encoding unit for generating a second code sequence for each group by performing the block encoding process on a first check symbol sequence in the first code sequence;
a generating unit for generating a third code sequence for each group by combining a second check symbol sequence in the second code sequence with the portion of the information sequence corresponding to each of the plurality of groups divided by the dividing unit so as to be associated with each other;
a combining unit for combining the third code sequences generated for the plurality of groups; and
a third encoding unit for generating a fourth code sequence by performing the block encoding process on the third code sequence combined by the combining unit.

3. The encoding apparatus of claim 2, wherein the dividing unit divides the information sequence such that a portion of the information sequence corresponding to one row forms one group when the information sequence is arranged in a two-dimensional array including a row having a length that is larger than a maximum code length in the block encoding process and a column having a length that is smaller than the maximum code length, the generating unit extends the length of each row of the two-dimensional array to perform combination such that the third code sequence is included in one row, and the third encoding unit performs the block encoding process on each column of the third code sequence combined by the combining unit.

4. The encoding apparatus of claim 2, wherein the second encoding unit makes combinations of the first check symbol sequences in the plurality of groups when the block encoding process is performed different from each other according to the orders of the first check symbol sequences.

5. A decoding apparatus, the apparatus comprising:
an input unit operative to receive a combined sequence of a second check symbol sequence in a second code sequence and an information sequence from an encoding apparatus and input the received sequence when the encoding apparatus:
performs at least a portion of a block encoding process on the information sequence to generate a first code sequence,
performs the block encoding sequence on a first check symbol sequence in the first code sequence to generate the second code sequence, and
combines a second check symbol sequence in the second code sequence with the information sequence;
an estimating unit to estimate the first code sequence by performing the same block encoding process as that performed by the encoding apparatus to generate the first code sequence on a portion corresponding to the information sequence in the received sequence input by the input unit;
a first processing unit to detect an error in the first check symbol sequence on the basis of the first check symbol sequence in the first code sequence estimated by the estimating unit and a portion corresponding to the second check symbol sequence in the received sequence input by the input unit; and
a second processing unit to detect an error in the portion corresponding to the information sequence on the basis of the first check symbol sequence whose error is detected by the first processing unit and the portion corresponding to the information sequence in the received sequence input by the input unit.

6. A decoding apparatus, the apparatus comprising:
an input unit operative to receive a code sequence including a third check symbol sequence from an encoding apparatus and input a received sequence when the encoding apparatus:
divides the information sequence into a plurality of groups,
performs at least a portion of a block encoding process on a portion of the information sequence corresponding to each of the plurality of groups to generate a first code sequence for each group,
performs the block encoding process on a first check symbol sequence in the first code sequence to generate a second code sequence for each group,
combines a second check symbol sequence in the second code sequence with the portion of the information sequence so as to be associated with each other, thereby generating a third code sequence for each group,
combines the third code sequences of the plurality of groups, and
performs the block encoding process on the combined third code sequence to generate a code sequence including a third check symbol sequence;
an estimating unit to estimate the first code sequence for each group by performing the same block encoding process as that performed by the encoding apparatus to generate the first code sequence on a portion corresponding to the information sequence in the received sequence input by the input unit;
a first processing unit to detect an error in the first check symbol sequence for each group on the basis of the first check symbol sequence in the first code sequence estimated by the estimating unit and a portion corresponding to the second check symbol sequence in the received sequence input by the input unit;
a second processing unit to detect an error in the portion corresponding to the information sequence for each group on the basis of the first check symbol sequence whose error is detected by the first processing unit and the portion corresponding to the information sequence in the received sequence input by the input unit; and
a third processing unit to correct the error in the portion corresponding to the information sequence on the basis of the portion corresponding to the information sequence whose error is detected by the second processing unit and portions corresponding to the second check symbol sequence and the third check symbol sequence in the received sequence input by the input unit.

7. The decoding apparatus of claim 5, wherein the first processing unit corrects the error and outputs the first check symbol sequence whose error is corrected to the second processing unit when an error is detected from the first check symbol sequence, and the second processing unit corrects the error when an error is detected from the portion corresponding to the information sequence.

8. The decoding apparatus of claim 6, wherein the first processing unit corrects the error and outputs the first check symbol sequence whose error is corrected to the second processing unit when an error is detected from the first check symbol sequence, and the second processing unit corrects the error when an error is detected from the portion corresponding to the information sequence.

9. The decoding apparatus of claim 6, wherein the encoding apparatus makes combinations of the first check symbol sequences in the plurality of groups when the block encoding process for generating the second code sequence is performed different from each other according to the orders of the first check symbol sequences, and the first processing unit detects and corrects the error using error detection information in the first check symbol sequences having different orders as erasure error information.

10. The decoding apparatus of claim 6, wherein the third processing unit performs erasure error correction as error correction while using the error detection information of each of the first code sequences as the erasure error information.

11. An encoding method, the method comprising:
generating a first code sequence by performing at least a portion of a block encoding process on an input information sequence;
generating a second code sequence by performing the block encoding process on a first check symbol sequence in the generated first code sequence; and
generating a third code sequence by combining a second check symbol sequence in the generated second code sequence with the input information sequence.

12. An encoding method, the method comprising:
dividing an input information sequence into a plurality of groups;
generating a first code sequence for each group by performing at least a portion of a block encoding process on a portion of the information sequence corresponding to each of the plurality of groups;
generating a second code sequence for each group by performing the block encoding process on a first check symbol sequence in the first code sequence;
generating a third code sequence for each group by combining a second check symbol sequence in the generated second code sequence with the portion of the information sequence in each of the plurality of divided groups so as to be associated with each other;
combining the generated third code sequences of the plurality of groups; and
generating a fourth code sequence by performing the block encoding process on the combined third code sequence.

13. The encoding method of claim 12, wherein the step of generating the second code sequence for each group includes combinations of the first check symbol sequences in the plurality of groups when the block encoding process is performed being different from each other according to the order of the first check symbol sequence.

14. A decoding method for an encoding apparatus that performs at least a portion of a block encoding process on an information sequence to generate a first code sequence, performs the block encoding sequence on a first check symbol sequence in the first code sequence to generate a second code sequence, and combines a second check symbol sequence in the second code sequence with the information sequence, the method comprising:
receiving the combined sequence of the second check symbol sequence in the second code sequence and the information sequence from the encoding apparatus and inputting the received sequence;
estimating the first code sequence by performing the same block encoding process as that performed by the encoding apparatus to generate the first code sequence on a portion corresponding to the information sequence in the input received sequence;
detecting an error in the first check symbol sequence, on the basis of the first check symbol sequence in the estimated first code sequence and the second check symbol sequence in the input received sequence; and
detecting an error in the portion corresponding to the information sequence in the received sequence, on the basis of the first check symbol sequence whose error is detected and the portion corresponding to the information sequence in the input received sequence.

15. A decoding method for an encoding apparatus that divides an information sequence into a plurality of groups, performs at least a portion of a block encoding process on a portion of the information sequence corresponding to each of the plurality of groups to generate a first code sequence for each group, performs the block encoding process on a first check symbol sequence in the first code sequence to generate a second code sequence for each group, combines a second check symbol sequence in the second code sequence with the portion of the information sequence so as to be associated with each other, thereby generating a third code sequence for each group, combines the third code sequences of the plurality of groups, and performs the block encoding process on the combined third code sequence to generate a code sequence including a third check symbol sequence, the method comprising:
receiving the code sequence including the third check symbol sequence from the encoding apparatus and inputting the received sequence;
estimating the first code sequence for each group by performing the same block encoding process as that performed by the encoding apparatus to generate the first code sequence on a portion corresponding to the information sequence in the received sequence;
detecting an error in the first check symbol sequence for each group, on the basis of the first check symbol sequence in the estimated first code sequence and a portion corresponding to the second check symbol sequence in the input received sequence;
detecting an error in the portion corresponding to the information sequence for each group, on the basis of the first check symbol sequence whose error is detected and the portion corresponding to the information sequence in the received sequence; and
correcting the error in the portion corresponding to the information sequence, on the basis of the portion corresponding to the information sequence whose error is detected and portions corresponding to the second check symbol sequence and the third check symbol sequence in the received sequence.

16. The decoding method of claim 15, wherein erasure error correction is performed as the error correction while using error detection information of each of the first code sequences as erasure error information when correcting the error in the portion corresponding to the information sequence.
